(19) United States
(12) Patent Application Publication
(10) Pub. No.: US 2023/0398793 A1
(43) Pub. Date: Dec. 14, 2023

(54) METHOD FOR PRINTING CONDUCTIVE TRACKS ON AN OBJECT AND ASSOCIATED ELECTRONIC FUNCTIONALISATION METHOD

(71) Applicants: INSTITUT POLYTECHNIQUE DE GRENOBLE, Grenoble (FR); UNIVERSITE GRENOBLE ALPES, Saint Martin D'Heres (FR); CENTRE NATIONAL DE LA RECHERCHE SCIENTIFIQUE, Paris (FR)

(72) Inventors: Philippe MARIN, Tencin (FR); Gioia FURIA, Pontcharra (FR); Didier CHAUSSY, Brie et Angonnes (FR); Davide BENEVENTI, Saint Martin D’Heres (FR)

(21) Appl. No.: 18/250,074

(22) PCT Filed: Oct. 15, 2021
(86) PCT No.: PCT/EP2021/078676

§ 371 Date: Apr. 21, 2023

(30) Foreign Application Priority Data
Oct. 22, 2020 (FR) 2010861

(51) Int. Cl. B41J 3/407; B05B 13/04; B25J 11/00; H05K 3/10

(52) U.S. Cl. CPC B41J 3/4073; B05B 13/0431; B25J 11/0075; H05K 3/102

(57) ABSTRACT

A method for printing at least one conductive track on the surface of an object, using at least one arm robot and at least one conductive ink print head. The object being arranged in a working area of the robot including taking a 3D scan of the object using a scanner mounted on the arm of the robot which controls the movement relative to the object. A digital model of the scanned portion of the surface of the object is constructed. A conductive track 10 is drawn digitally on the previously constructed digital model. Depending on the drawing of the conductive track, a path for the print head is generated. The conductive track is printed using the print head mounted on the arm of the robot which controls the movement relative to the object, by following the previously generated path.

### TECHNICAL FIELD OF THE INVENTION

The present invention relates to the field of systems and methods for printing a conductive track on the surface of an object. It is applicable particularly advantageously to the electronic functionalisation of objects, regardless of their geometry.

### PRIOR ART

Several methods already exist for printing conductive tracks on a surface of a three-dimensional (3D) object.

In particular, patent document WO 2016/097932 proposes using:
a robot with multiple degrees of freedom for gripping and moving an object on which conductive tracks are to be printed, and
an inkjet print head for discharging a conductive ink onto the surface of the object,
   the robot being configured to adjust the position of the object during printing so that the object moves along a predetermined spatial path relative to the print head, the print head being at any moment substantially perpendicular to a target surface of the object to be printed on at said moment in time.

A disadvantage of the system according to patent document WO 2016/097932 is that it is not, or is at least poorly, adapted for use on a production line. It would in fact be necessary to stop the production line at least in order to change the object to be functionalised. Furthermore, to ensure the precision of the positioning of the conductive tracks, it would be necessary to know exactly how the object was picked up by the robot, which presents certain difficulties, and is relatively incompatible with the desired level of industrialization. Furthermore, the system according to patent document WO 2016/097932 is limited to objects of a size, shape, and principally weight, compatible with the handling capacities of the robot.

It is therefore an object of the present invention to propose a method for printing a conductive track onto the surface of an object which makes it possible to overcome at least one of the aforementioned disadvantages. Another object of the present invention is to propose a method for electronically functionalising an object, which makes it possible to reduce the time between the design and manufacture of prototypes, even preproduction runs, of the object.

Other objects, features and advantages of the present invention will become apparent from the following description and accompanying drawings. It is understood that other advantages may be incorporated.

### SUMMARY OF THE INVENTION

To achieve this objective, according to a first aspect of the invention, a method for printing at least one conductive track on the surface of an object is provided. The method uses at least one robot arm with multiple degrees of freedom and at least one print head for conductive ink. At least a portion of the object is arranged in a working space of said at least one robot.

The printing method comprises the following steps:
taking a 3D scan of at least a portion of the surface of the object using a scanner mounted on a robot arm which ensures its movement relative to the object,
constructing, from the 3D scan taken, a digital model of the scanned portion of the surface of the object using CAD software,
digitally drawing, on the previously constructed digital model, a conductive track using CAD software,
generating, on the basis of the drawing of the conductive track, a trajectory for the print head using CAD software, and
printing said at least one conductive track using the print head mounted on a robot arm which ensures its movement relative to the object following the previously generated trajectory.

Thus, the method according to the first aspect of the invention allows the 3D scanning and conductive ink printing operations to be carried out:
in a flexible and modular manner, and/or
in a simple manner in terms of use and programming, and/or
with simplified software and user interface, and/or
with a shorter time between the design and manufacture of prototypes or preproduction runs than is currently the case, and/or
in a manner compatible with industrial environments, and/or
in a way that can be integrated into existing automated production lines.

Optionally, the printing method introduced above may also have at least one of the following features which can be taken separately or in combination.

According to one example, the object is a three-dimensional object.

According to another example, the method further comprises, following the step of taking the 3D scan of the object and before the step of constructing said digital model, a step of locating the position of the object relative to a reference mark (TCP—Tool Center Point) of said at least one robot.

According to another example, the drawing of the conductive track is performed directly on the constructed digital model or is generated by projecting a two-dimensional (2D) digital model of the conductive track on the constructed digital model.

According to another example, said at least one robot comprises at least one six-axis articulated robot arm.

According to another example, the scanner comprises a laser triangulation sensor. The laser triangulation sensor may comprise at least one among a laser spot sensor and a laser line sensor.

According to another example, the printing step also comprises the use of contact (pneumatic or volumetric extrusion through needles) or non-contact (piezoelectric ink drop jet) dosing systems.

According to another example, multiple conductive tracks are printed, which together form at least one printed circuit.

According to another example, the method also comprises a step of processing at least one conductive track using a spray valve mounted on a robot arm which ensures its displacement relative to the object, if necessary following the previously generated trajectory.

According to another example, the method further comprises, prior to the step of taking the 3D scan, an initialisation step comprising generating a digital model of at least one among the scanner, the print head and a possibly associated dosing system, a pick-and-place machine with integrated vision device and a spray valve.

According to another example, at least two among the scanner, the print head and a possibly associated dosing system, a pick-and-place machine with integrated vision device and a spray valve are mounted on the same robot arm.

Alternatively or in addition to the previous example, at least two among the scanner, the print head and a possibly associated dosing system, a pick-and-place machine with integrated vision device and a spray valve are mounted on different robot arms. According to this example, a conveyor can be provided which is configured to convey the object from a working space of a first robot to a working space of another robot. Alternatively or in addition, at least two robots are arranged at different, and possibly successive, stations of the same production line.

Another aspect of the invention relates to a computer program product comprising instructions, which, when they are performed by at least one processor, executes at least the steps of the printing method introduced above.

Another aspect of the invention relates to a method of electronically functionalising an object, comprising:
the method of printing at least one conductive track on the surface of an object as introduced above, so as to print on the object a plurality of conductive tracks forming a printed circuit and
placing electronic components at predefined locations on the printed circuit board using a pick-and-place machine, with an integrated vision device, mounted on a robot arm.

Thus, the method according to the first aspect of the invention makes it possible to position electronic components so as to electronically functionalize an object:
in a flexible and modular manner, and/or
in a simple manner in terms of use and programming, and/or
with simplified software and user interface, and/or
with a reduced time, compared to that which exists, between the design and the manufacture of prototypes or preproduction runs, and/or
in a manner compatible with industrial environments, and/or
in a manner that can be integrated into existing automatic production lines.

Another aspect of the invention relates to a computer program product comprising instructions, which, when performed by at least one processor, executes at least the steps of the electronic functionalisation method as introduced above.

### BRIEF DESCRIPTION OF THE FIGURES

The aims, objects, as well as the features and advantages of the invention are described in more detail in the description below with reference to an embodiment of the latter which is illustrated by the following accompanying drawings in which:

FIG. 1 shows a flowchart of an embodiment of the method for printing conductive tracks on the surface of an object according to the first aspect of the invention and an embodiment of the electronic functionalisation method of an object according to another aspect of the invention.

FIG. 2 shows the robot arm 2 used according to one embodiment of the methods according to the invention.

FIG. 3 shows an exploded view of various tools and their support fixed onto the robot arm as illustrated in FIG. 2.

FIG. 4 shows a perspective view of an object as functionalised by implementing the methods according to the invention.

The drawings are given by way of example and are not limiting for the invention. They are graphic representations which are intended to facilitate understanding of the invention and are not necessarily to the scale of practical applications.

### DETAILED DESCRIPTION OF THE INVENTION

A “pick-and-place” machine is defined as a machine for picking and placing.

A “printed circuit” is defined as a set of conductive tracks arranged on a support, formed here by the object, and enabling a set of electronic components to be electrically connected to one another, with the aim of producing an electronic circuit.

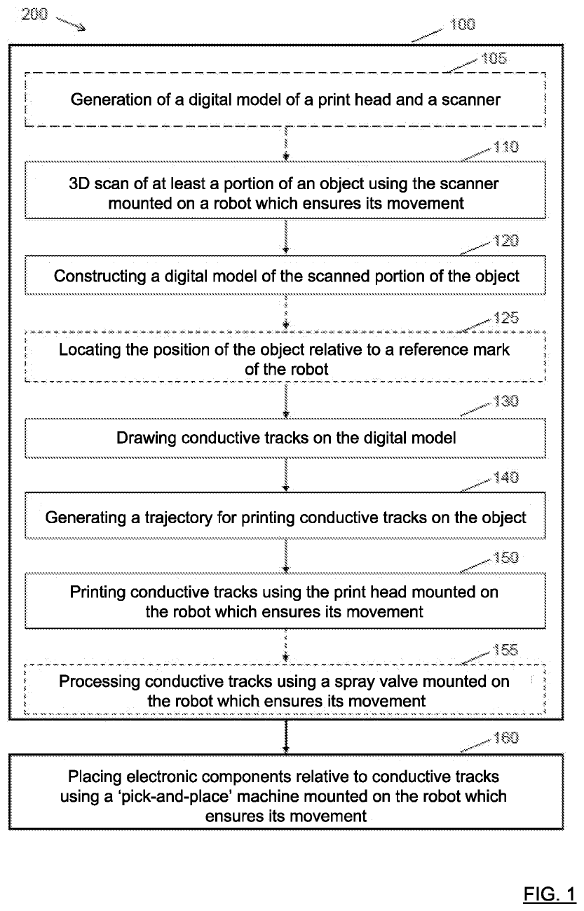

With reference to FIG. 1, an embodiment of the first aspect of the invention provides for printing 100 conductive tracks 10 on the surface of an object 1 by using a robot arm 2 with multiple degrees of freedom and at least one print head 3 for conductive ink. The robot 2 may more particularly be a six-axis articulated robot. Such a robot is advantageously controlled and common in industrial use.

Contrary to the printing method described in document WO 2016/097932, here it is the object 1 which is arranged in a working space of the robot 2; the tools necessary for printing are carried by the robot 2 which ensures their displacement relative to the object 1.

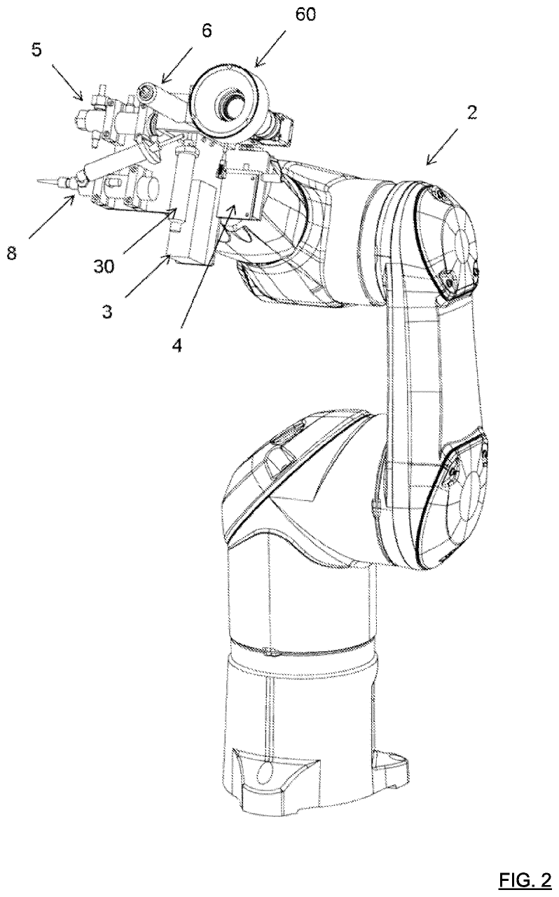

Thus, and as illustrated in FIGS. 1 to 4, the method 100 comprises the following steps:
taking 110 a 3D scan of at least a portion of the surface of the object 1 using a scanner 4 mounted on a robot arm 2, which ensures its movement relative to the object 1,
constructing 120, from the 3D scan taken 110, a digital model of the scanned portion of the surface of the object 1 using CAD software,
digitally drawing 130, on the previously constructed digital model 120, a conductive track 10 using CAD software,
generating 140, on the basis of the drawing 130 of the conductive track 10, a trajectory for the print head 3 using CAD software, and
printing 150 said at least one conductive track 10 using the print head 3 mounted on a robot arm 2, which ensures its movement relative to the object 1 following the previously generated trajectory 140.

It should be noted that, in particular for the purposes of 3D scanning, the object and more particularly the surface of the object to be scanned 110, is preferably opaque or made opaque. It should also be noted that the object can advantageously be a so-called multi-material object.

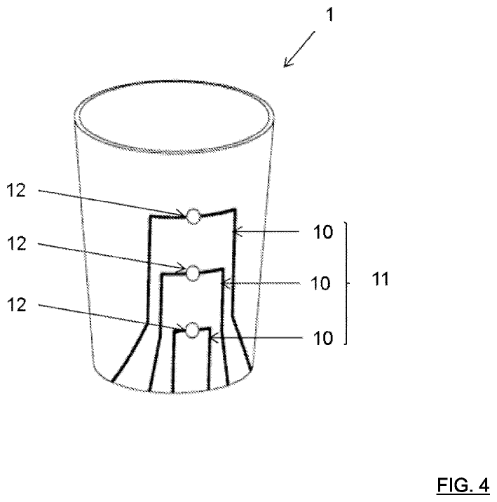

With further reference to FIG. 1, but also with reference to FIG. 4, an embodiment of a second aspect of the invention provides continuing the printing method 100 according to its first aspect with a step of placing 160 electronic components 12 at predefined locations of a printed circuit 11 formed by a plurality of conductive tracks 10 by using a “pick-and-place” machine 6, with an integrated vision device 60, mounted on the robot arm 2, so as to electronically functionalize the object 1.

Thus, the object 1 remains in the same position during the printing method 100 and if necessary the functionalisation method 200. It is the tools required for printing 100 and if necessary for the functionalisation 200 that are displaced relative to the object 1 by being attached to the arm of the robot 2.

Therefore, the object 1 can be of any weight. Indeed, the object 1 rests for example on a platform, defining the working space of the robot 2, which can be adapted to receive an object of any weight. The object 1 may also be of any shape. As the scanner is configured to perform a 3D scan, the object is effectively not limited to a 2D shape; the scanned portion of the object 1 may have a curved surface. Furthermore, the 3D scan may only relate to a portion of the object 1. As soon as the portion of the object 1 concerned by the 3D scan enters the working space of the robot, the object 1 can have any dimensions. Rather, in the printing system described in document WO 2016/097932, the object necessarily has a reduced weight in order to be moved by the robot (a six-axis robot arm can generally allow objects weighing up to 3 kg to be moved), with a shape allowing it to be gripped by the robot, and with dimensions limited by those of the working space of the robot.

Furthermore, with a view to industrialization, the methods 100 and 200 according to the invention have the advantage, contrary to the printing system described in document WO 2016/097932, of not requiring the production line to be stopped each time the object to be functionalised is changed. Two or three robots 2 may even be provided according to the invention, to act simultaneously or successively on the object 1. For example, at least two robots 2 are arranged at different and possibly successive stations of the same production line. Furthermore, the use of a plurality of robots 2 each carrying one or more of the tools necessary for printing 100 and if necessary for functionalisation 200 may be provided in conjunction with that of a conveyor configured to convey the object from a working space of a first robot to a working space of a following robot along the production line.

The present invention also makes it possible to avoid problems, inherent to the printing system described in document WO 2016/097932, of defining the way in which the robot has gripped the object. Indeed, the object 1 may remain, during methods 100 and 200 according to the invention in a fixed position, it may be sufficient to ensure that the initial positioning of the object 1 is known with sufficient accuracy to implement the invention. If necessary, a step may be provided consisting of locating 125 the position of the object 1 with respect to a reference mark (TCP—Tool Center Point) of the robot 2, in particular following the 3D scan 110 and before the step of constructing 120 said digital model, so as to ensure that the steps of the method are performed accurately with the CAD software. Indeed, the calibration of the robot 2 and the automatic positioning of the robot 2 relative to the object 1 are made possible by this locating step 125, even if the positioning of the object 1 in the working space of the robot 2 is not predefined.

A further advantage of the printing method according to the first aspect of the invention lies in the fact that it is compatible with making the drawing 130 of the conductive track 10 either directly on the constructed digital model 120 or by projecting a 2D digital model of the conductive track 10 onto the constructed digital model 120.

Furthermore, prior to the step of taking 110 the 3D scan, it is easy to perform, potentially once and for all, an initialisation step comprising the generation 105 of a digital model of at least one among the print head 3 and a possible associated dosing system the scanner 4, a spray valve 5, and a pick-and-place machine 6 with integrated vision device 60. Thus, the distance of each tool at any moment when it is used relative to the object 1 can be determined digitally with high precision, and potentially for the entire duration of use of a robot 2 provided with the same tools. It should be noted that it is possible that this can be ensured in other ways, involving for example a distance sensor, such as a laser sensor, and/or a vision device, such as a camera.

A specific embodiment of a robotic cell used according to the printing method 100 and if necessary the functionalisation method 200 will now be described by way of a non-limiting example.

The robot arm 2 can comprise more particularly a 6-axis robot arm from the TX2-60 range and its CS9 controller provided by the company Stäubli. The CS9 controller can also be associated with an SP2 manual control unit.

The print head 3 may comprise more particularly a microdosing valve such as that provided under reference number MDV 3200A by the company VERMES and a precision volumetric dosing pump.

The dosing system 30 associated with the print head 3 may comprise more particularly a precision volumetric dosing pump, such as one sold under the brand name preeflow® eco-PEN300.

The scanner 4 can comprise more particularly one of the laser sensors provided by the company Micro-Epsilon, and in particular one sold with reference number optoNCDT 1420.

The spray valve 5 may more particularly comprise a stainless steel spray valve, such as one sold by the company FISNAR® with reference number SV1000SS. It can be used in addition to print heads 3 and 8 for depositing i) conductive inks on large surfaces or ii) a varnish for protecting electronic circuits.

The pick-and-place machine 6 may comprise more particularly a CV-X400 industrial vision device and associated peripheral devices, as provided by the company KEYENCE.

The vision device 60 integrated into the pick-and-place machine 6 can comprise more particularly a camera and an LED ring light. The picking and placing function can be achieved more particularly by a pick-up capillary of electronic components connected to a vacuum pump via a solenoid valve controlled by the robot arm controller 2.

A needle metering valve 8 can also be provided, which comprises a pressurised cartridge containing the conductive ink to be deposited and a pneumatic needle valve driven by the controller of the robot arm 2. This valve may more particularly be one of those sold by the company VIEWEG®.

It should be noted that each of the print head 3 and its dosing system 30, the scanner 4, the spray valve 5 and the dosing valve 8 can be functionally connected and linked to the controller of the robot arm 2, if necessary via a suitable controller and/or converter.

Furthermore, these different elements are connected to one another via different connections such as RT Ethernet slave buses, an EtherCAT master bus, Ethernet TCP/IP ports and RS232 serial ports and other modular connections (digital I/O, analogue I/O).

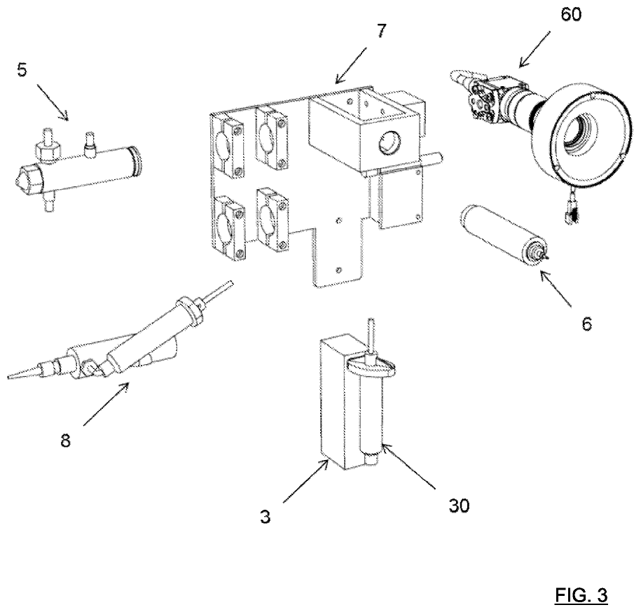

It should also be noted, with reference to FIG. 3, that the different tools used according to the selected embodiment, and in particular the one illustrated, in which all the tools 3, 4, 5, 6 and 8 used are fixed to the same robot 2, can be attached via a support 7 for example in the form of a board.

It should be noted that this specific configuration, as well as other possible configurations, have the following advantages:
a cell cost of below 150 k€,
an installation time of 30 to 60 minutes, and
easy to learn, i.e. a training time of about ½ day.

This can be arranged in conjunction with a cell. The cell defines for example all or part of the working space of the robot 2. A majority of elements 2, 3, 4, 5, 6, 7 and 8 can be arranged in the cell.

Such a robotic cell meets the needs of research laboratories or generally small companies, i.e. it is adapted to be operated by people with no particular skills in robotics, and for the production of prototypes with the shortest possible set-up time. The cell is also designed, installed and maintained at low cost.

A dedicated interface is proposed which has been developed to link with a visual programming language and environment that runs on the Rhinoceros 3D application, known as Grasshopper®, for automating the whole process, creating and transferring the robot 2 program to make the cell usable by people with no skills in robotics.

It should also be noted that the board 7 and the various tools 3, 4, 5, 6 and 8 potentially attached to it have a total weight of advantageously less than 3 kg.

Furthermore, the safety of the user can be ensured by an automatic stop installed on a door of the cell. Thus, when the robot 2 is operating in automatic mode, opening the door causes the robot 2 to stop immediately. The fault caused must be corrected by a specific button to allow the root 2 to power up again. In addition, any emergency stop from pressing a red alert button will also cause the robot 2 to stop immediately.

The invention is not limited to the embodiments described above and extends to all embodiments covered by the claims.

1. A method for printing at least one conductive track on the surface of an object, the method using at least one robot arm with multiple degrees of freedom and at least one print head for conductive ink, at least a portion of the object being arranged in a working space of said at least one robot, the method comprising the following steps:
taking a 3D scan of at least a portion of the surface of the object using a scanner mounted on a robot arm which ensures its movement relative to the object,
constructing, from the 3D scan taken, a digital model of the scanned portion of the surface of the object using CAD software,
digitally drawing, on the previously constructed digital model, a conductive track using CAD software,
generating, on the basis of the drawing of the conductive track, a trajectory for the print head using CAD software, and
printing said at least one conductive track using the print head mounted on flail the robot arm which ensures its movement relative to the object following the previously generated trajectory.

2. The method according to claim 1, further comprising, following the step of taking the 3D scan of the object and before the step of constructing said digital model, a step consisting of locating the position of the object with respect to a reference mark of said at least one robot.

3. The method according to claim 1, wherein the drawing of the conductive track is performed directly on the constructed digital model.

4. The method according to claim 1, wherein said at least one robot comprises at least one six-axis articulated robot arm.

5. The method according to claim 1, wherein the scanner comprises a laser triangulation sensor.

6. The method according to claim 5, wherein the laser triangulation sensor comprises at least one among a laser spot sensor and a laser line sensor.

7. The method according to claim 1, wherein the printing step also comprises the use of contact or non-contact dosing systems.

8. The method according to claim 1, wherein a plurality of conductive tracks are printed which together form at least one printed circuit.

9. The method according to claim 1, comprising a step of processing at least one conductive track by using a spray valve mounted on an arm of the robot which ensures its displacement relative to the object, if necessary by following the previously generated trajectory.

10. The method according to claim 1, comprising, prior to the step of taking the 3D scan, an initialisation step comprising generating a digital model of at least one among the print head, the scanner, a spray valve, and a pick-and-place machine with integrated vision device.

11. The method according to claim 1, wherein at least two among the print head, the scanner, a spray valve, and a pick-and-place machine with integrated vision device are mounted on a same robot arm.

12. The method according to claim 1, wherein at least two among the print head, the scanner, a spray valve, and a pick-and-place machine with integrated vision device are mounted on different robot arm(s).

13. A method of electronic functionalisation of an object, comprising the method of printing at least one conductive track on the surface of an object according to claim 1 so as to print on the object a plurality of conductive tracks forming a printed circuit and placing electronic components at predefined locations on the printed circuit by using a pick-and-place machine, with integrated vision device, mounted on an arm of the robot.

14. A computer program product comprising instructions, which, when they are executed by at least one processor, executes at least the steps of the method of printing at least one conductive track on the surface of an object according to claim 1.

15. A computer program product comprising instructions, which, when they are executed by at least one processor, executes at least the steps of the method of electronically functionalising an object according to claim 13.

16. The method according to claim 1, wherein the drawing of the conductive track is generated by projecting a two-dimensional digital model of the conductive track on the constructed digital model.

17. The method according to claim 1, comprising, prior to the step of taking the 3D scan, an initialisation step comprising generating a digital model of at least one among the print head and an associated dosing system, the scanner, a spray valve, and a pick-and-place machine with integrated vision device.

18. The method according to claim 1, wherein at least two among the print head and an associated dosing system, the scanner, a spray valve, and a pick-and-place machine with integrated vision device are mounted on a same robot arm.

19. The method according to claim 1, wherein at least two among the print head and an associated dosing system, the scanner, a spray valve, and a pick-and-place machine with integrated vision device are mounted on different robot arm(s).
